(19) United States
(12) Patent Application Publication
(10) Pub. No.: US 2024/0057358 A1
(43) Pub. Date: Feb. 15, 2024

(54) METHOD FOR ENCAPSULATING AND PROCESSING SOLAR CELL ROOF PANEL

(71) Applicant: Magna Exteriors Inc., Aurora (CA)

(72) Inventors: Alexis Baltazar-y-Jimenez, Troy, MI (US); Parvinder Walia, Shelby Township, MI (US); Marisa Jayne, Troy, MI (US)

(73) Assignee: Magna Exteriors Inc., Aurora (CA)

(21) Appl. No.: 18/448,603

(22) Filed: Aug. 11, 2023

Related U.S. Application Data
(60) Provisional application No. 63/397,179, filed on Aug. 11, 2022.
(60) Provisional application No. 63/483,415, filed on Feb. 6, 2023.

(51) Int. Cl. H10K 30/88; H10K 30/50; H10K 71/00

(52) U.S. Cl. CPC H10K 30/88; H10K 30/50; H10K 71/851

(57) ABSTRACT

A solar cell base layer surrounded by a layer of protective material that has a softening temperature which is useable in post processing of the solar cell in a thermoforming environment.

### CROSS-REFERENCE TO RELATED APPLICATIONS

This application is a Non-Provisional Patent Application and claims benefit of U.S. Provisional Patent Application No. 63/397,179, filed Aug. 11, 2022, and U.S. Provisional Patent Application No. 63/483,415, filed Feb. 6, 2023. The disclosures of the above applications are incorporated herein by reference.

### FIELD OF THE INVENTION

The present invention relates to a method for encapsulating a perovskite or other thermally stable solar panel and processing the encapsulated solar cell into a roof panel.

### BACKGROUND OF THE INVENTION

It is a goal in the art to incorporate solar panels into vehicle surfaces to provide charging benefits using vehicle roofs and other panel surfaces for electricity to assist in charging of batteries in a vehicle. In order to manufacture solar panels into vehicle parts the solar panels must be able to withstand panel processing conditions. In particular, thermal degradation of conventional solar panels does not allow them to readily be used in high temperature molding methods used in manufacture of vehicle parts.

It has been found that thermal degradation of perovskite solar cell, encapsulant and cover layers, is a problem. While there have been various methods of modifying these panels they all fall short for use in processing of vehicle panels. Thus, CA2803592A1 describes sunroof panel with solar charging system for a motor vehicle but does not describe encapsulation, or downstream processing of the panel. CN110010767A describes an encapsulation method but on a glass substrate which is not useful in molding operations. US20210184062A1 describes automotive solar cell roof panel using laminated glass which is not useful in molding vehicle panels. U.S. Ser. No. 10/158,145B2 describes a solid state battery on a flexible polymer sheet but use of perovskite is not reported in the claims. SONOS motors opted for the use of silicon-based solar films attached to polycarbonate panels. This has the disadvantage of increasing labor, weight, and assembly costs.

Therefore, it is a goal of the present invention to provide a solar panel which is not subject to thermal degradation found in manufacturing of a molded panel.

### SUMMARY OF THE INVENTION

The invention describes a novel method to process a flexible perovskite solar cell without thermal degradation of the required encapsulant layers, for use in high-volume manufacturing.

The present invention provides a thermoformable solar cell material that is not subject to thermal degradation during manufacturing processes and operations. The material includes a perovskite solar cell base layer surrounded by a layer of protective material that has a softening temperature which is useable in post processing of the solar cell in a thermoforming environment.

This is achieved by combining a perovskite solar cell with a polycarbonate outer encapsulation by using temperature thermoforming, double-belt lamination, and/or overmolding with clear polycarbonate (PC).

The invention proposes removing the EVA encapsulant such as found in a typical solar cell such as a perovskite solar cell and replacing it with a PET or PC films with high barrier properties using double-belt lamination, and followed by thermoforming, or spray transfer molding. EPDM can also be used to displace the EVA encapsulant with the added possibility of cross-linking by e-beam before overmolding. Replacing the EVA with PET or PEC requires only softening the materials, as opposed to melting them, and prevents thermal damage to the perovskite cell while maintaining water-tight seal and high vapor barrier properties. The resulting laminate can then be trimmed to net-shape for processing in conventional polymer processing equipment, such as: compression molding, or overmolding using roll-to-roll in-mold-decoration equipment to encapsulate and protect the solar cell from environmental conditions and improve the durability of the solar roof assembly.

Additionally, the use of a high temperature melting PET or PC film would offer a higher degree of protection in standard overmolding or in-cold decoration process. Alternatively, the EVA encapsulant can be eliminated and the with the use of PC based front and back sheets and additional encapsulation during PC overmolding, sufficient moisture resistance can be provided while minimizing thermal degradation during overmolding.

The use of the present invention provides: 1. Increased durability in the field; 2. Prevents degradation due to heat and moisture; and, 3. Facilitates processing for high volume manufacturing.

With these goals in mind vehicle body and trim panels are produced which are serviceable on vehicles and at the same time generate solar energy for charging of vehicle batteries and the like. As examples, parts such as removeable or fixed roof panels, vehicle hoods, trunk and frunk lids and even horizontal trim are all used for capturing and storing vehicle energy.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a sectional view of the present invention.

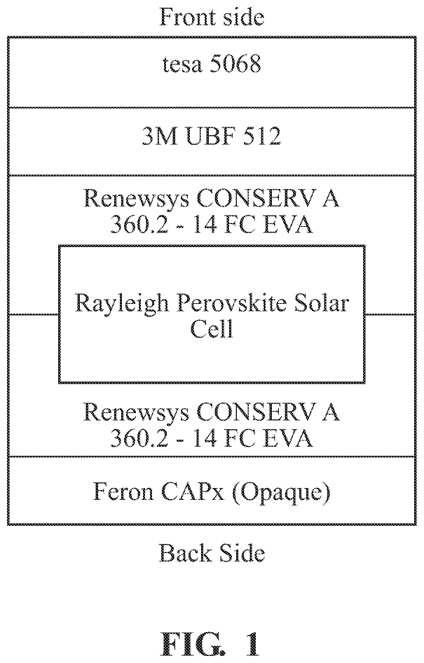

### DETAILED DESCRIPTION OF THE PREFERRED EMBODIMENTS

The following description of the preferred embodiment(s) is merely exemplary in nature and is in no way intended to limit the invention, its application, or uses.

A thermoformable solar cell of the present invention using a perovskite cell as an example is shown generally at 10. The cell includes a central perovskite solar cell or other thermally stable solar cell base layer 12. In the present invention the solar cell 12 is encapsulated in a thermoformable material 14. The thermoformable material allows the cell to be formed in various thermoforming processes, for instance for incorporating the solar cell into a body panel or to fit in a certain size or shaped area of a vehicle or other application.

A perovskite solar cell base layer or other thermally stable solar cell base layer surrounded by a layer of protective material that has a softening temperature which is useable in post processing of the solar cell in a thermoforming environment.

The solar cell of the present invention is produced by encapsulating the perovskite solar cell base layer in a thermoformable material from the group consisting essentially of Polyethylene terephthalate (PET), polycarbonate (PC), Polyethylene naphthalate (PEN) and mixtures thereof. Spray transfer molding. EPDM can also be used to displace the EVA encapsulant with the added possibility of cross-linking by e-beam before overmolding. Suitable encapsulation materials have thermoforming temperatures of between 280 to about 315 degrees Celsius. The encapsulation is accomplished by forming the film using an injection molding tool, a double belt lamination process, thermoforming, stamping, compression molding, injection-compression, PUR overmolding, and combinations of these processes. In a preferred embodiment encapsulation is accomplished by overmolding of a transparent or translucent material. Preferred materials include polycarbonate, translucent polypropylene/thermoplastic olefins (PP/TPO), polymethyl methacrylate (PMMA), translucent acrylonitrile butyl styrene (ABS), liquid silicone runner (LSR) or mixtures thereof.

A final shaped part is produced during encapsulation of the perovskite encapsulation. In one embodiment the perovskite material is placed on a layer of thermoformable PET, PC or PEN and thereafter a compatible layer is used on the other side of the perovskite for encapsulation. In any case the thermoformable materials used may be formed in a post processing step after the assembly it formed to produce a final shaped product.

For example, post processing may include trimming of the part, such as by cutting with a CNC machine. The formed part is also suitable for further overmolding processes.

Preferred properties of the polymers selected include high optical transparency and flexibility, temperature tolerances which allow thermoforming, good chemical stability and conductivity, which also provided oxygen and moisture barriers to protect the perovskite base.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A thermoformable solar cell construction comprising:
a solar cell base layer surrounded by a layer of protective material that has a softening temperature which is useable in post processing of the solar cell in a thermoforming environment.

2. The solar cell of claim 1 further comprising encapsulating the solar cell base layer in a material from the group consisting essentially of PET, PC, PEN and mixtures thereof, as well as EPDM to displace the EVA encapsulant.

3. The solar cell of claim 2 wherein the encapsulation is accomplished by forming the film using an injection molding tool, double belt lamination, thermoforming, stamping, compression molding, injection-compression, PUR-overmolding, and/or spray transfer molding, this latter in virtue to its low pressure and low temperature requirement for processing.

4. The solar cell construction of claim 2 wherein the encapsulation is accomplished by overmolding with a transparent or translucent material.

5. The solar cell of claim 2 wherein the encapsulation is accomplished by overmolding with polycarbonate, translucent PP/TPO, PMMA, translucent ABS, liquid silicone runner (LSR) or mixtures thereof.

6. The solar cell of claim 2 wherein a final shaped vehicle part is produced during encapsulation of the perovskite encapsulation.

7. The solar cell of claim 1 where the materials allow processing in temperatures of from about 280 to about 315 degrees Celsius.

8. A process for forming a shaped part comprising a solar cell comprising the steps of:
A. Providing a solar cell base layer;
B. Encapsulating the solar cell base layer in a thermoformable material having a forming temperature of from about 280 to 315 degrees Celsius;
C. Post processing the product of step B in a thermoforming mold for providing a formed part including a solar cell component.

9. The process of claim 6 wherein the thermoformable material is selected from the group of PET, PC, PEN and mixtures thereof.

10. The process of claim 7 wherein the encapsulation is accomplished by forming the film using an injection molding tool, double belt lamination, thermoforming, stamping, compression molding and/or spray transfer molding, this latter in virtue to its low pressure and low temperature requirement for processing.

11. The process of claim 8 wherein a final shaped part is produced during encapsulation of solar cell.

12. The process of claim 1 wherein the solar cell base layer is placed on a thermoformable layer prior to applying a top layer of thermoformable material for encapsulation of the perovskite.

13. The process of claim 1 wherein post processing includes cutting of a shape.

14. The process of claim 11 wherein CNC cutting is used for cutting of the shape.

15. The process of claim 1 wherein the post processing includes overmolding of materials onto the formed part.

16. The process of claim 15 wherein the encapsulation is accomplished by overmolding with a transparent or translucent material

17. The process of claim 16 wherein the encapsulation is accomplished by overmolding with polycarbonate, translucent PP/TPO, PMMA, translucent ABS, liquid silicone runner (LSR) or mixtures thereof.
